(19) United States
(12) Patent Application Publication
(10) Pub. No.: US 2013/0127515 A1
(43) Pub. Date: May 23, 2013

(54) VOLTAGE DIVIDING CIRCUIT

(71) Applicants: Hung-Chang YU, Hsinchu (TW); Shu-Meng YANG, Xincheng Township (TW); Yue-Der CHIH, Hsinchu City (TW)

(72) Inventors: Hung-Chang YU, Hsinchu (TW); Shu-Meng YANG, Xincheng Township (TW); Yue-Der CHIH, Hsinchu City (TW)

(73) Assignee: TAIWAN SEMICONDUCTOR MANUFACTURING COMPANY, LTD., Hsinchu (TW)

(21) Appl. No.: 13/302,260

(22) Filed: Nov. 22, 2011

(51) Int. Cl. H03L 5/00

(52) U.S. Cl. 327/333

(57) ABSTRACT

A voltage divider is disclosed that includes a plurality of components connected in series having respective input terminals, respective output terminals, and a reference voltage node at the connection between one of the input terminals and one of the output terminals. The voltage divider also includes a level shifter having a input terminal coupled to the reference voltage node and having a output terminal supplying an output reference voltage.

### BACKGROUND

In order to reduce the power dissipation of electronic devices, more technologies employ computational applications predicated on lower voltages. While many logical and memory operations were previously executed with a voltage source of 5 volts (V), modifications in the preferred source voltage of circuits have steadily reduced that value close to the threshold voltage of a gate and/or diode (i.e., at or below 1 V, close to the typical threshold voltage of about 600-900 millivolts). This results in reduced power consumption of numerous devices that rely on computing and memory, such as laptop computers, music players, and mobile phones.

On the other hand, many of the same electronic devices employ technologies such as flash memory circuitry, which utilize high-voltage circuits for memory access operations (i.e., read and/or write operations). In those operations, voltage sources and charge pumps increase the operational voltage to a level that can reach or exceed 13 to 14 volts. Thus, the ability to meet both conditions, i.e., low-voltage operational voltages and high-voltage source voltages, determines the ability to provide high speed and reliability with low power consumption.

A voltage-dividing circuit utilizing only a series of diodes can provide a reference voltage at a connection point between diodes within the plurality. For instance, if a plurality has a number of diodes N, then the connection between diode_{N} and diode_{N-1} provides a reference voltage node with a voltage value equal to the voltage across diode_{N}. Typically, a threshold voltage (also referred to as a turn-on voltage) of each diode ranges between about 600 millivolts and about 900 millivolts. For instance, if a circuit is utilized to divide a 13 V circuit, such as in a flash memory operation, and diodes in the plurality have a threshold voltage of approximately 800 millivolts, then 16 diodes may be used in the plurality. For a 40V supply, 50 diodes having an 800-millivolt threshold are utilized in the plurality. While the circuit is useful, the voltage supplied at reference node is limited by the threshold value of diode or diodes used. In other words, the output voltage of reference node is at least equal to the threshold voltage of a single diode. For applications using lower voltage values, such as a logic circuit operating below 1 V, the supplied voltage at the reference node may be too high.

### BRIEF DESCRIPTION OF THE DRAWINGS

One or more embodiments are illustrated by way of example, and not by limitation, in the figures of the accompanying drawings, wherein, wherever possible, elements having the same reference numeral designations represent like elements throughout. The accompanying drawings are incorporated herein and are part of this disclosure.

FIG. 1 is a functional block diagram of a sub-threshold voltage divider according to an embodiment.

FIG. 2 is a simplified circuit diagram of a sub-threshold voltage divider according to an embodiment.

FIG. 3 is a graph of waveforms utilizing the voltage divider of FIG. 2.

FIG. 4 is a simplified circuit diagram of a sub-threshold voltage divider according to another embodiment.

FIG. 5 is a graph of waveforms utilizing the voltage divider of FIG. 4.

### DETAILED DESCRIPTION

The following disclosure provides many different embodiments, or examples, for implementing different features described below. Specific examples of components and arrangements are described below to simplify the present disclosure. These are, of course, merely examples and are not intended to be limiting. For example, various features may be arbitrarily drawn in different scales for simplicity and clarity.

Although suitable for different uses, the apparatus and method herein are described with reference to embodiments for use with memory devices, such as those using flash memory. One of ordinary skill will be able to apply the disclosure to a wide variety of technologies. For example, light emitting diode (LED) display and liquid crystal display (LCD) technologies for viewing video are additional technologies that may employ the embodiments described below. While the descriptions discuss high-voltage applications in the context of flash memory, which typically operates at approximately 13 V, different high-voltage values may be utilized. For instance, in display technologies, a voltage source may provide a voltage value in excess of 40 V. Therefore, the described embodiments are not limited to a particular maximum voltage value.

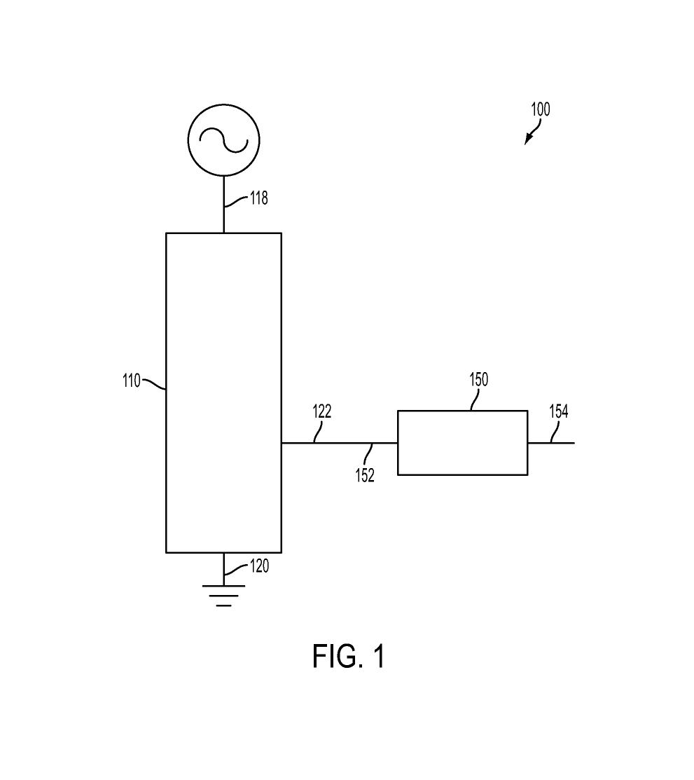

FIG. 1 is a functional block diagram of a sub-threshold voltage divider 100 according to an embodiment. The sub-threshold voltage divider 100 comprises two primary functional elements, a primary divider 110 and a level shifter 150. Primary divider 110 has a reference voltage output terminal 122 coupled to an input terminal 152 of level shifter 150.

In addition to terminal 122, primary divider 110 also has an input terminal 118 and an output terminal 120. Input terminal 118 receives a high-voltage source supply voltage, such as a voltage supplied during a flash memory operation. Output terminal 120 is connected to a ground or reference signal. Primary divider 110 consists of a plurality of components, such as a plurality of diodes connected in series. Thus, input terminal 118 can be an input terminal of one component of the plurality, while output terminal 120 can be an output terminal of another component of the plurality.

In addition to input terminal 152, level shifter 150 also has an output terminal 154. Level shifter 150 receives the voltage input from the primary divider 110 (via reference voltage output terminal 122) at input terminal 152. Prior to output at output terminal 154, level shifter 150 lowers the voltage to a final output voltage value. Thus, even though the primary divider 110 may be limited by a threshold voltage of an individual component within the plurality of components, the level shifter 150 is configured to reduce a total output voltage to less than the threshold voltage of a discrete component within primary divider 110. The output voltage of level shifter 150 can be represented by the following equation:

V_{OUT}=V_{TH}*α

In the above equation, V_{OUT} is the voltage supplied by output terminal 154 of level shifter 150. V_{OUT} is equal to the threshold voltage of a diode in the plurality (V_{TH}), or more specifically the threshold voltage of the last diode in the plurality, multiplied by a factor α. The factor α is a coefficient between zero and one. Thus, level shifter 150 reduces the reference voltage by a proportional amount, which can be configured based on design parameters. For example, if diodes having a threshold voltage of 900 millivolts are used in a voltage divider, and the desired reference voltage is 600 millivolts, then a level shifter 150 can be configured to produce an a of approximately 0.67.

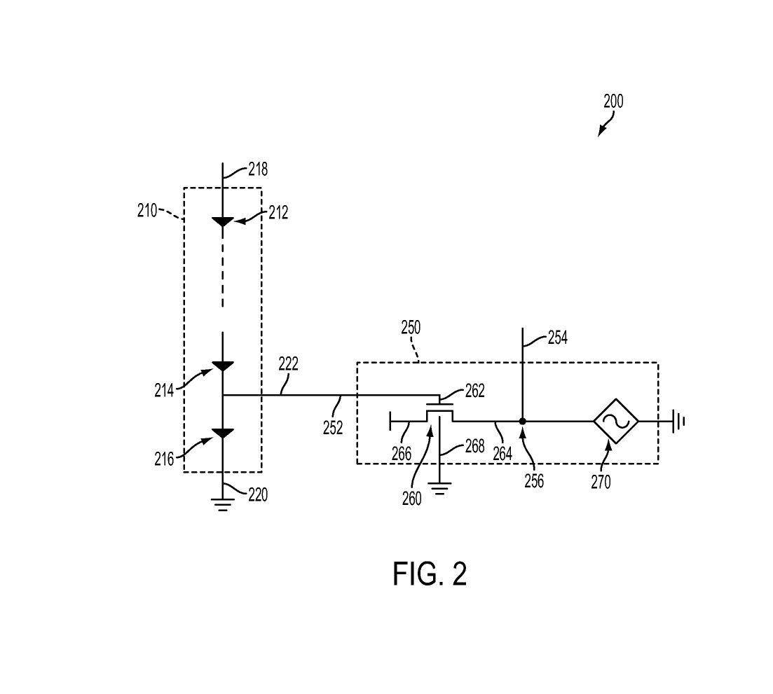

FIG. 2 depicts a simplified circuit diagram of a sub-threshold voltage divider 200 according to an embodiment. As shown in FIG. 1 in functional block form, voltage divider 200 includes a primary divider 210 and a level shifter 250. A primary reference voltage node terminal 222 of primary divider 210 is connected with an input terminal 252 of level shifter 250.

The primary divider 210 comprises a plurality of diodes having a number N diodes. As depicted in FIG. 2, primary divider 210 includes a diode₁ 212, diode_{N-1} 214, and a diode_{N} 216. The number of diodes connected in series between diode₁ 212 and diode_{N-1} 214 varies as described above. Each diode has an input terminal and an output terminal. As a component, primary divider 210 has an input terminal 218, which can be the input terminal of diode₁ 212, or alternatively a terminal electrically coupled with the input terminal of diode₁ 212. Primary divider 210 has an output terminal 220, which can be an output terminal of diode_{N} 216, or alternatively a terminal electrically coupled with the output terminal of diode_{N} 216. An output terminal of diode₁ 212 is connected to an input terminal of diode₂ (not shown or numbered), and so on throughout the plurality of diodes in primary divider 210, such that each of the diodes is connected in series.

Level shifter 250 has an input terminal 252 and an output terminal 254. In the depicted embodiment, level shifter 250 comprises a transistor 260 and a controllable current source 270. In the depicted embodiment, input terminal 252 is a gate 262 of transistor 260. Output 254 is an output terminal from an output reference node 256. One terminal of controllable current source 270 and a drain 264 of transistor 260 are each coupled to the output reference node 256 as well. The bulk 268 of transistor 260 and a second terminal of controllable current source 270 are grounded. A source 266 of transistor 260 is floating.

In this configuration, the controllable current source can be varied in order for the reference voltage supplied at output 254 to be less than that of the voltage supplied at reference voltage node 222. If the threshold voltages of diode_{N} 216 and transistor 260 are similar, then receiving a signal at reference terminal 222 with a voltage above the threshold voltage of diode_{N} 216 will cause transistor 260 to be activated. Thus, if transistor 260 is off, the operation of level shifter 250 is that of a short circuit and there is no power supplied. The result is that no voltage is supplied at output 254 due to the short circuit. However, if transistor 260 is on, the current source provides power. The power supplied by the current source is thus configurable and can be selected so that the voltage is less than the threshold voltage of a transistor or diode.

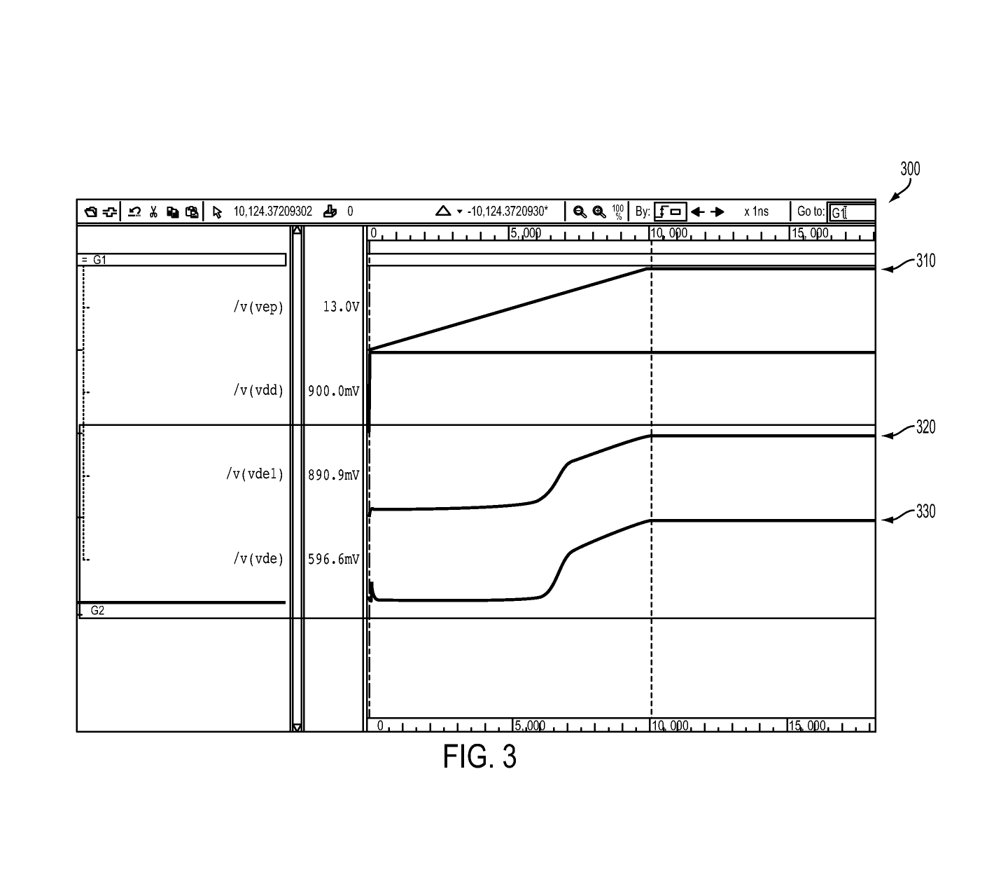

FIG. 3 shows a graph 300 of various waveforms utilizing the voltage divider 200 of FIG. 2. The high-voltage input is represented by line 310. The voltage at reference node 222 is represented as vde1, graphed as line 320, and is 890.9 mV. Thus, the value of line 320 is very nearly equal to a theoretical threshold voltage of diode_{N} 216 (900 mV). The output reference voltage from the level shifter 250 is 596.6 mV as represented by line 330 (shown as voltage vde). Therefore, level shifter 250 supplies a much lower reference voltage than the threshold voltage of diode_{N} 216. That is to say, vde1 is less than 67% of the voltage supplied by a voltage divider without level shifter 250.

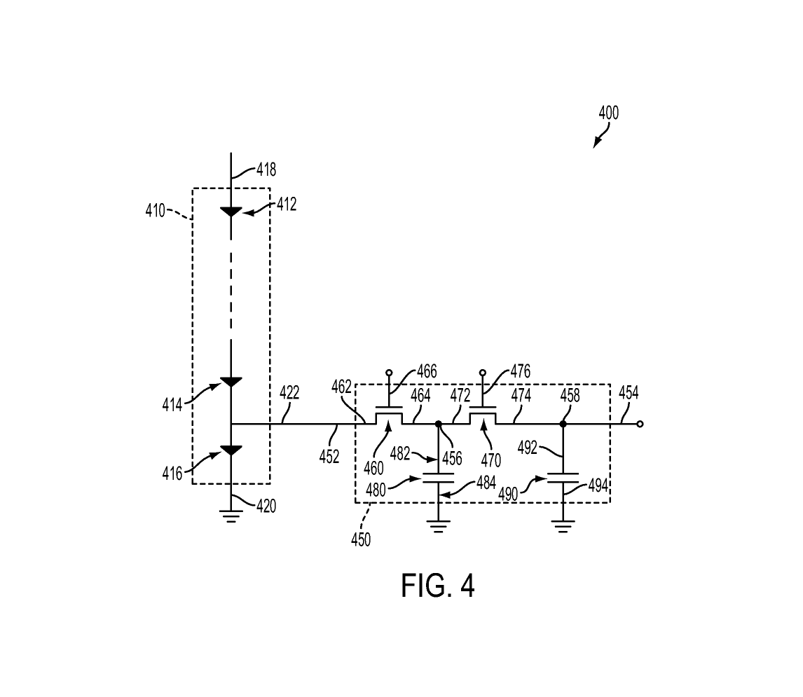

FIG. 4 is a simplified circuit diagram of an exemplary sub-threshold voltage divider 400 according to another embodiment. Voltage divider 400 also includes a primary divider 410 and a level shifter 450. The primary divider 410 is similar in nature to primary divider 210 and thus corresponding components are numbered by using the reference numerals shown in FIG. 2 and adding 200. Also, the connections between primary divider 410 and level shifter 450, along with the other components coupled to primary divider 410, are similar to those described above.

Level shifter 450 also has an input terminal 452 and an output terminal 454. However, level shifter 450 comprises transistors 460 and 470 and capacitors 480 and 490. Transistor 460, transistor 470, and capacitor 480 are connected at a node 456. Transistor 470 and capacitor 490 are connected at an output reference voltage node 458. Input terminal 452 is a source 462 of transistor 460. Output terminal 454 is an output coupled to output reference voltage node 458.

Node 456 is the connection point of a drain 464 of transistor 460 coupled to a source 472 of transistor 470 and input terminal 482 of capacitor 480. At output reference voltage node 458, a drain 474 of transistor 470 is coupled to an input terminal 492 of capacitor 490, thus providing the point of connection of drain 474, input 492, and output terminal 454.

A gate 466 of transistor 460 and a gate terminal 476 of transistor 470 are each coupled to corresponding voltage signals, denoted as vsw1 and vsw2. An output terminal 484 of capacitor 480 and an output terminal 494 of capacitor 490 are each grounded. Level shifter 450 is configurable based on the parameters of transistors 460 and 470, and capacitors 480 and 490. Thus, depending on the threshold voltage of each of transistor 460 and 470, the supplied voltage, and the capacitance of the capacitors 480 and 490, the reference voltage supplied at output terminal 454 can be varied as desired.

For instance, in an embodiment, transistors 460 and 470 have a threshold voltage of approximately 900 millivolts. Capacitor 480 has a capacitance of 30 femtofarads, while capacitor 490 has a capacitance of 14.4 femtofarads. The approximate output reference voltage from this configuration is 600 millivolts. Transistors and capacitors possessing other threshold and capacitance values can be selected for the desired voltage division operation.

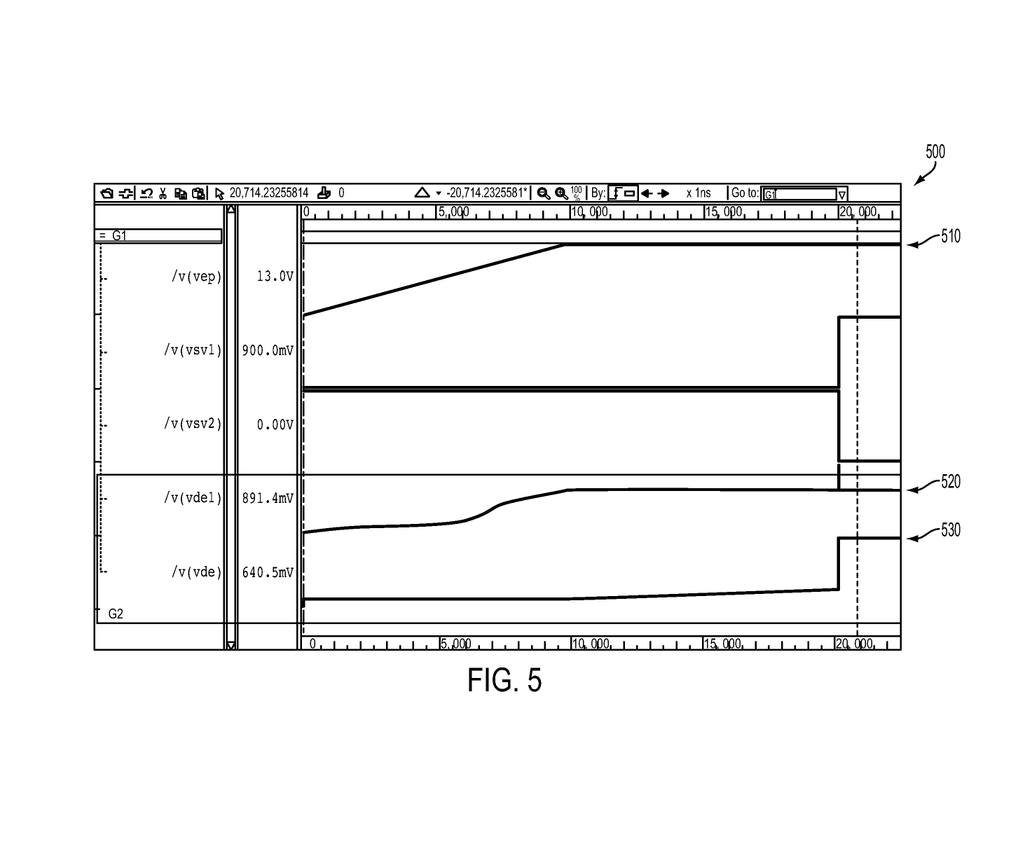

FIG. 5 shows a graph 500 of various waveforms utilizing the voltage divider 400 of FIG. 4. The high-voltage input is represented by line 510. The voltage at reference node 422 is represented as vde1, graphed as line 520, and is 891.4 mV. Again, the value of line 520 is very nearly equal to the theoretical threshold voltage of the diode (900 mV). The output reference voltage from level shifter 450 is 640.5 mV as represented as voltage vde and by line 530. In this instance, level shifter 450 supplies a much lower reference voltage than the threshold voltage of diode_{N} 416, as vde1 is less than 72% of the voltage supplied by a voltage divider without level shifter 450.

The choice of which type of level shifter to implement will depend on various design considerations, such as the amount of chip space occupied by the various components, process/voltage/temperature (PVT) variations, assorted manufacturing costs, etc. For instance, the manufacture of the controllable current source disclosed in the embodiment shown in FIG. 2 may be more susceptible to PVT variations, but require less chip space and be cheaper to produce. On the other hand, the embodiment shown in FIG. 4 may have just the opposite characteristics and therefore be utilized when chip space is not at a premium, but when there is a desire to minimize variations in operation (i.e., PVT).

A voltage divider is disclosed comprising a plurality of components connected in series having respective input terminals, respective output terminals, and a reference voltage node at the connection between one of the input terminals and one of the output terminals. The voltage divider also comprises a level shifter having a input terminal coupled to the reference voltage node and having a output terminal supplying an output reference voltage.

Also disclosed is a voltage divider including a plurality of diodes connected in series having an input terminal, an output terminal, and a reference voltage node. The voltage divider further includes a capacitive level shifter having an input terminal coupled to the reference voltage node and having an output terminal supplying an output reference voltage.

A voltage-dividing apparatus for applications below a turn-on threshold voltage is disclosed that includes a plurality of N diodes connected in series, where N is an integer. A first diode of the plurality has an input terminal electrically coupled to a high voltage source and an output terminal connected to a next diode in the plurality. An Nth diode of the plurality has an input terminal connected to an output terminal of the (N−1)th diode and has a ground terminal connected to ground. The apparatus also comprises a level shifter having an input terminal and an output terminal. The input terminal of the level shifter is electrically coupled to the input terminal of the Nth diode. The output terminal of the level shifter provides an output reference voltage.

It will be readily seen by one of ordinary skill in the art that the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A voltage divider comprising:
a plurality of components connected in series having respective input terminals, respective output terminals, and a reference voltage node at the connection between one of the input terminals and one of the output terminals; and
a level shifter having an input terminal coupled to the reference voltage node and having an output terminal configured to supply an output reference voltage.

2. The voltage divider of claim 1, wherein the level shifter comprises a transistor and a controllable current source.

3. The voltage divider of claim 2, wherein the transistor is configured to have a gate coupled to the reference voltage node, a source, a bulk coupled to ground, and a drain coupled to the output terminal of the level shifter.

4. The voltage divider of claim 2, wherein the controllable current source has an input coupled to the output terminal of the level shifter and an output coupled to ground.

5. The voltage divider of claim 2, wherein an output of the level shifter is configured to be smaller than a threshold voltage of the transistor.

6. The voltage divider of claim 1, wherein the plurality of components includes N components connected in series, wherein N is an integer, and wherein a first component includes a first input terminal which is coupled to a voltage source, and wherein an Nth component of the plurality has an input terminal connected to an output terminal of the (N−1)th component and has an output terminal connected to ground.

7. The voltage divider of claim 6, wherein the plurality of components are diodes.

8. The voltage divider of claim 6, wherein the first input terminal of the plurality is configured to be coupled to flash memory circuit including a charge pump.

9. The voltage divider of claim 8, wherein the high voltage is greater than 12 volts.

10. The voltage divider of claim 6, wherein the first output terminal of the plurality is configured to be coupled to ground.

11. A voltage divider for low-voltage applications, the voltage divider comprising:
a plurality of diodes connected in series having an input terminal, an output terminal, and a reference voltage node; and
a capacitive level shifter having an input terminal coupled to the reference voltage node and having an output terminal configured to supply an output reference voltage.

12. The voltage divider of claim 11, wherein the capacitive level shifter further comprises:
a first transistor and a second transistor coupled in series;
a first capacitor coupled to a node between the first transistor and the second transistor; and
a second capacitor coupled to the output of the second transistor.

13. The voltage divider of claim 12, wherein a first switching input is coupled to a gate of the first transistor and a second switching input is coupled to a gate of the second transistor.

14. The voltage divider of claim 13, wherein a source of the first transistor is coupled to the reference voltage node and the drain is coupled with the first capacitor.

15. The voltage divider of claim 13, wherein a source of the second transistor is coupled to the first capacitor and the drain is coupled with the second capacitor and a reference output voltage node.

16. The voltage divider of claim 12, wherein an output of the capacitive level shifter is configured to be smaller than a threshold voltage of a transistor in the capacitive level shifter.

17. A voltage divider for applications below a turn-on threshold voltage, the voltage divider comprising:
a plurality of N diodes connected in series, wherein N is an integer, and wherein a first diode of the plurality has an input terminal electrically coupled to a high voltage source and an output terminal connected to a next diode in the plurality, and wherein an Nth diode of the plurality has an input terminal connected to an output terminal of the (N−1)th diode and has a ground terminal connected to ground; and
a level shifter having an input terminal and an output terminal, wherein the input terminal is electrically coupled to the input terminal of the Nth diode, and wherein the output terminal is configured to supply an output reference voltage.

18. The voltage divider of claim 17, wherein the level shifter comprises a transistor and a controllable current source.

19. The voltage divider of claim 17, wherein the level shifter comprises a capacitive level shifter including at least one transistor and at least one capacitor.

20. The voltage divider of claim 17, wherein the high voltage source provides an input voltage of 12 V or greater.
